(19) United States
(12) Patent Application Publication
(10) Pub. No.: US 2024/0154580 A1
(43) Pub. Date: May 9, 2024

(54) SEMICONDUCTOR DEVICE AND TEST METHOD

(71) Applicant: LAPIS Technology Co., Ltd., Yokohama (JP)

(72) Inventor: Yifan WANG, Yokohama (JP)

(73) Assignee: LAPIS Technology Co., Ltd., Yokohama (JP)

(21) Appl. No.: 18/502,068

(22) Filed: Nov. 5, 2023

(30) Foreign Application Priority Data
Nov. 9, 2022 (JP) 2022-179850

(51) Int. Cl. H03F 1/34; H03F 3/45

(52) U.S. Cl. CPC H03F 1/342; H03F 3/45475; H03F 3/45932

(57) ABSTRACT

The disclosure has a semiconductor IC chip formed with: a feedback amplification circuit, generating an output voltage supplied to a capacitive load by transmitting a current corresponding to a difference between an input voltage and a feedback voltage to the first pad via a first wiring; and a feedback resistor, receiving a voltage received by the second pad via a second wiring not connected with the first wiring, and generating, as the feedback voltage, a voltage obtained by dividing the voltage received via the second wiring.

### CROSS-REFERENCE TO RELATED APPLICATION

This application claims priority under 35 USC 119 from Japanese Patent application No. 2022-179850 filed on Nov. 9, 2022, the disclosure of which is incorporated by reference herein.

### BACKGROUND

### Technical Field

The disclosure relates to a semiconductor device, and particularly relates to a semiconductor device in which a circuit supplying a voltage to an externally connected load is formed and a test method.

### Related Art

A semiconductor device including a constant voltage circuit that generates a voltage with a constant voltage value and outputs the voltage as an output voltage has been commercialized.

In addition, as such constant voltage circuit, a constant voltage circuit including a differential amplifier and a transistor has been proposed (see, for example, Japanese Application Laid-open No. 2011-13726). The differential amplifier receives a reference voltage by using an non-inverting input end of the differential amplifier itself, and receives, by the non-inverting input end, a feedback voltage obtained by dividing an output voltage by using a resistor. The transistor generates the output voltage by supplying to the resistor a current in accordance with the output of the differential amplifier. Such constant voltage circuit is a negative feedback amplification circuit that operates so that the voltage value of the output voltage is equal to the reference voltage by outputting a current corresponding to the difference between the reference voltage and the output voltage of the constant voltage circuit itself, and a phase compensation circuit that prevents oscillation is built therein.

Such phase compensation circuit included in the negative feedback amplification circuit is designed to take into consideration the gain and the output current required by the negative feedback amplification circuit, the properties of the connected load, etc., to ensure a phase margin for preventing oscillation.

However, when the negative feedback amplification circuit is formed in one semiconductor IC chip with another circuit group, oscillation may occur due to the position where the negative feedback amplification circuit is disposed in the semiconductor IC chip.

Accordingly, care needs to be taken to dispose the negative amplification circuit at a place where oscillation does not occur. Moreover, since the degree of freedom for disposing the another circuit group is thus decreased, there is an increased possibility to have a dead space in the semiconductor IC chip. Therefore, the chip size may be increased.

Thus, the disclosure provides a semiconductor device and a test method capable of suppressing oscillation of the negative feedback amplification circuit regardless of the position where the negative feedback amplification circuit is disposed in the semiconductor IC chip.

### SUMMARY

An aspect of the disclosure provides a semiconductor device. The semiconductor device has a semiconductor IC chip formed with a first pad and a second pad, a feedback amplification circuit, and a feedback resistor. The feedback amplification circuit generates an output voltage supplied to a capacitive load by transmitting a current corresponding to a difference between an input voltage and a feedback voltage to the first pad via a first wiring. The feedback resistor receives a voltage received by the second pad via a second wiring not connected with the first wiring, and generates, as the feedback voltage, a voltage obtained by dividing the voltage received via the second wiring.

Another aspect of the disclosure provides a test method for performing a test on the semiconductor IC chip by using a tester having a first probe needle and a second probe needle. The first probe needle and the second probe needle are commonly connected to an end of a capacitive load for testing. The test is performed in a state in which a needle tip of the first probe needle is brought into contact with the first pad of the semiconductor IC chip and a needle tip of the second probe needle is brought into contact with the second pad of the semiconductor IC chip.

### BRIEF DESCRIPTION OF THE DRAWINGS

FIG. 1 is a diagram illustrating a configuration of a semiconductor device 100 as a first embodiment.

FIG. 2 is an equivalent circuit diagram representing wiring resistances of respective wirings connecting a conventional regulator circuit, a pad electrode of a semiconductor IC chip, an external terminal of a package, and a capacitive load by using symbols of resistors.

FIG. 3 is a Bode diagram illustrating an example of frequency properties of the regulator circuit in the case where the regulator circuit is disposed in a region in the vicinity of the pad electrode in the semiconductor IC chip.

FIG. 4 is a layout diagram schematically illustrating a position where the regulator circuit is disposed in the semiconductor IC chip.

FIG. 5 is a Bode diagram illustrating an example of frequency properties of the regulator circuit in the case where the regulator circuit is disposed in a region away from the pad electrode in the semiconductor IC chip.

FIG. 6 is an equivalent circuit diagram representing wiring resistances of respective wirings connecting a regulator circuit 10, a semiconductor IC chip 20, a package 30, and a load CL shown in FIG. 1 by using symbols of resistors.

FIG. 7 is a diagram illustrating a configuration of a test system at the time of testing the semiconductor IC chip 20.

FIG. 8 is a diagram illustrating a configuration of a semiconductor device 100A as a second embodiment.

FIG. 9 is a diagram illustrating a configuration of a semiconductor device 100B as a third embodiment.

FIG. 10 is a diagram illustrating a configuration of a test system at the time of testing a semiconductor IC chip 20A.

FIG. 11 is an equivalent circuit diagram representing wiring resistances of respective wirings connected between the regulator circuit 10, the semiconductor IC chip 20A, the package 30, and a load CLq by using symbols of resistors in the test system shown in FIG. 10.

FIG. 12 is a diagram illustrating a configuration of a semiconductor device 100C as a fourth embodiment.

FIG. 13 is a diagram illustrating a configuration of a test system at the time of testing a semiconductor IC chip 20B.

FIG. 14 is a diagram illustrating a configuration of a semiconductor device 100D as a fifth embodiment.

FIG. 15 is a diagram illustrating stored contents of a memory ME.

### DETAILED DESCRIPTION

According to the disclosure, the oscillation of the negative feedback amplification circuit can be suppressed regardless of the position where the negative feedback amplification circuit is disposed in the semiconductor IC chip. Therefore, it is possible to dispose the negative feedback amplification circuit and another circuit group in the semiconductor IC chip without having dead space, and the chip size can be reduced.

In the following, the embodiments of the disclosure are described with reference to the drawings.

### Embodiment 1

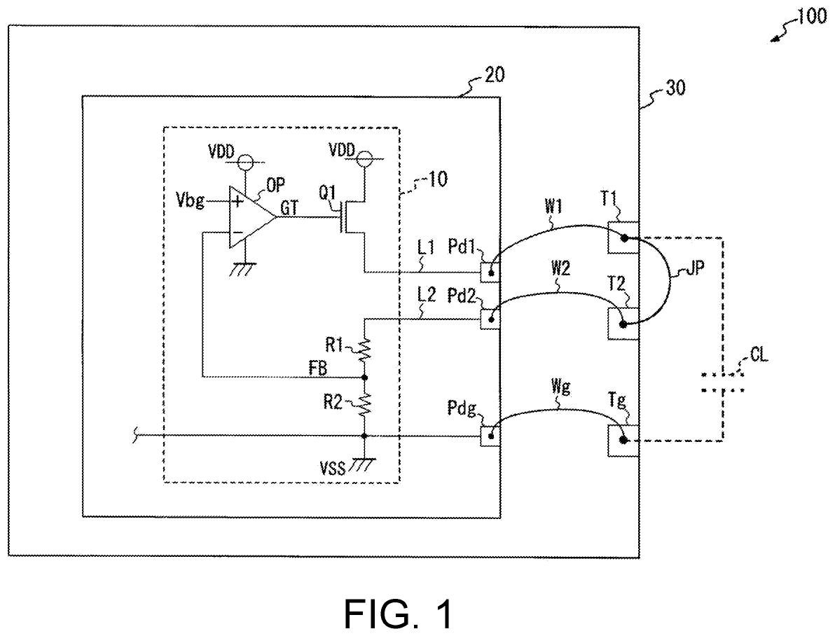

FIG. 1 is a diagram illustrating a configuration of a semiconductor device 100 as a first embodiment according to the disclosure.

As shown in FIG. 1, the semiconductor device 100 includes a semiconductor IC chip 20 and a package 30 accommodating the semiconductor IC chip 20. The semiconductor IC chip 20 is formed with a regulator circuit 10 and another circuit group (not shown).

The regulator circuit 10 generates a constant voltage having a voltage value corresponding to a predetermined reference voltage, and supplies the constant voltage to a capacitive load CL externally connected with external terminals T1 (T2) and Tg of the package 30.

The regulator circuit 10 is a negative feedback amplification circuit including a differential amplifier OP, a P-channel MOS-type output transistor Q1, and feedback resistors R1 and R2.

The differential amplifier OP receives a feedback voltage FB generated by the feedback resistors R1 and R2 by using the inverting input end of the differential amplifier OP itself, and receives a predetermined reference voltage Vbg by using the non-inverting input end of the differential amplifier OP itself. The differential amplifier OP supplies a current corresponding to the difference between the feedback voltage FB and the reference voltage Vbg to the output end of the differential amplifier OP itself. The differential amplifier OP supplies an output signal GT having a voltage generated at its own output end to the gate of the output transistor Q1. A phase compensation circuit (not shown) is built in the differential amplifier OP. The phase compensation circuit is designed to take into consideration the gain of the phase compensation circuit itself and the output current, the properties of the load CL, etc., and secure a phase margin for preventing oscillation.

A power voltage VDD is applied to the source of the output transistor Q1, and the drain of the output transistor Q1 is connected with a pad electrode Pd1 of the semiconductor IC chip 20 via an intra-chip wiring L1.

An end of the feedback resistor R1 is connected with a pad electrode Pd2 of the semiconductor IC chip 20 via an intra-chip wiring L2. The other end of the feedback resistor R1 is connected with an end of the feedback resistor R2, and the other end of the feedback resistor R2 is connected with a pad electrode Pdg of the semiconductor IC chip 20 and the another circuit group (not shown). A ground voltage VSS is applied to the pad electrode Pdg and the other end of the feedback resistor R2.

The pad electrode Pd1 is connected with the external terminal T1 of the package 30 via a bonding wire W1. The pad electrode Pd2 is connected with the external terminal T2 of the package 30 via a bonding wire W2. The pad electrode Pdg is connected with the external terminal Tg of the package 30 via a bonding wire Wg. The external terminals T1 and T2 are short-circuited by a metal wiring JP.

With such configuration, the output transistor Q1 supplies a current corresponding to the difference between the reference voltage Vbg and the feedback voltage FB to an end of the feedback resistor R1 via the intra-chip wiring L1, the bonding wire W1, the metal wiring JP, the bonding wire W2, and the intra-chip wiring L2. Accordingly, at the external terminal T1 (T2) of the package 30, a voltage (referred to as output voltage) corresponding to the difference between the reference voltage Vbg and the feedback voltage FB is generated, and the output voltage is supplied to the capacitive load CL connected with the external terminals T1 (T2) and Tg. At this time, by supplying, as the feedback voltage FB, the voltage obtained by dividing the generated output voltage by using the feedback resistors R1 and R2 to the inverting input end of the differential amplifier OP, the voltage value of the output voltage is maintained at a constant voltage value corresponding to the reference voltage Vbg.

Meanwhile, in the semiconductor device 100, the drain of the output transistor Q1 and an end of the feedback resistor R1 included in the regulator circuit 10 are not directly connected. Instead, as shown in FIG. 1, the drain of the output transistor Q1 and the end of the feedback resistor R1 are connected via the intra-chip wiring L1, the pad electrode Pd1, the bonding wire W1, the external terminal T1, the metal wiring JP, the external terminal T2, the bonding wire W2, and the intra-chip wiring L2.

According to the disclosure, by adopting such wiring configuration, it is possible to suppress the oscillation of the regulator circuit 10 regardless of the position where the regulator circuit 10 is disposed in the semiconductor IC chip 20.

In the following, the reasons why oscillation is suppressed by adopting the configuration shown in FIG. 1 are described.

Firstly, the case where oscillation occurs in a conventional regulator circuit in the state in which a capacitive load is externally connected with a semiconductor device where such regulator circuit is formed is described.

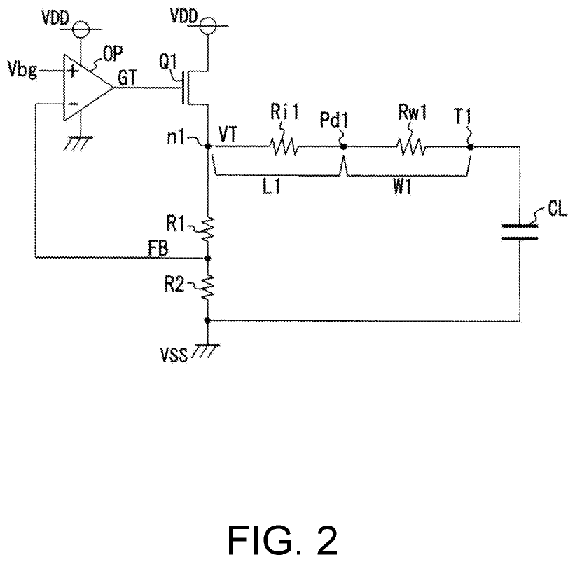

FIG. 2 is an equivalent circuit diagram representing wiring resistances of respective wirings connecting the conventional regulator circuit, a pad electrode of a semiconductor IC chip, an external terminal of a package, and a capacitive load by using symbols of resistors.

It is noted that, as shown in FIG. 2, the regulator circuit, like the regulator circuit 10 shown in FIG. 1, is formed by the differential amplifier OP, the output transistor Q1, and the feedback resistors (R1, R2). However, in the conventional regulator circuit as shown in FIG. 2, the drain of the output transistor Q1 is connected with an end of the feedback resistor R1 via an intra-chip wiring, the voltage generated at a connection node n1 of such connection is supplied to the capacitive load CL connected with the external terminal T1 of the package via the intra-chip wiring L1, the pad electrode Pd1 of the semiconductor IC chip, and the bonding wire W1.

At this time, the intra-chip wiring L1 has a wiring resistance Ri1 and the bonding wire W1 has a wiring resistance Rw1. Since the wiring resistance Rw1 of the bonding wire W1 is a low resistance about 0.1 ohm, it is substantially configured that the load CL is connected in series with the wiring resistance Ri1 of the intra-chip wiring L1 connecting the regulator circuit and the pad electrode Pd1.

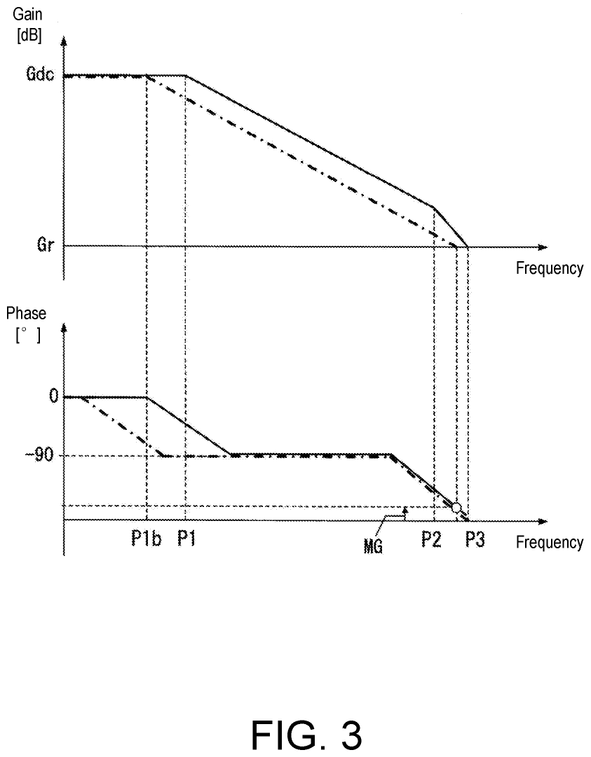

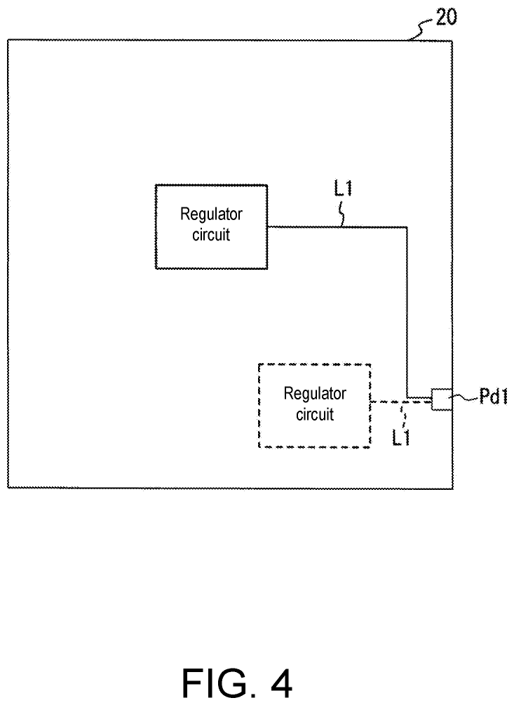

FIG. 3 is a Bode diagram illustrating an example of frequency properties of the regulator circuit in the case where the regulator circuit 10 is disposed in a region in the vicinity of the pad electrode Pd1, i.e., a region surrounded by the broken line in FIG. 4, in the semiconductor IC chip 20.

In FIG. 3, the dot-chain line illustrates the properties of the case where phase compensation is performed by a phase compensation circuit included in the differential amplifier OP, and the solid line illustrates the properties where phase compensation is not performed.

As indicated by the solid line of FIG. 3, in the case where phase compensation is not performed, a constant gain Gdc is obtained in the case where the gain of the regulator circuit is equal to or less than a frequency P1 (referred to as “pole frequency P1” in the following), and the gain of the regulator circuit decreases at a slope of 20 [dB/dec], as the frequency increases with the pole frequency P1 serving as the extreme point. In addition, the gain of the regulator decreases at a slope of 40 [dB/dec], as the frequency increases with a frequency P2 (referred to as “pole frequency P2” in the following) higher than the pole frequency P1 serving as the extreme point.

In addition, as indicated by the solid line of FIG. 3, the phase is delayed as the frequency increases with a frequency P1b, which is 1/10 of the pole frequency P1, serving as the extreme point, and is constantly delayed by 90° at a frequency 10 times of the pole frequency P1. In addition, as the frequency continues to increase with a frequency that is 1/10 of the pole frequency P2 as the extreme point, the phase thereof becomes delayed.

Meanwhile, as indicated by the dot-chain line of FIG. 3, in the case where phase compensation is performed, the gain of the regulator circuit decreases at a slope of 20 [dB/dec] as the frequency increases with a predetermined first frequency lower than the pole frequency P1 serving as the extreme point.

In addition, as indicated by the dot-chain line of FIG. 3, the phase is delayed as the frequency increases with a predetermined second frequency lower than the frequency P1b serving as the extreme point, and is constantly delayed by 90° at the pole frequency P1. In addition, as the frequency continues to increase with a frequency that is 1/10 of the pole frequency P2 as the extreme point, the phase thereof becomes delayed.

Meanwhile, the differential amplifier OP oscillates in the case where the phase delay generated at the feedback voltage FB is 360° and the gain is 1 or more. At this time, since the phase delay amount at the feedback resistor is 180°, in order to suppress the oscillation, it is necessary to reduce the output phase delay amount as much as possible to be less than 180°.

By performing phase compensation, as shown in the properties of the dot-chain line of FIG. 3, although the frequency at which a desired gain Gr is obtained decreases, the phase delay at the frequency at which the desired gain Gr is obtained can also be reduced by a phase difference MG with respect to the phase delay in the case where phase compensation is not performed, as indicated by the solid line of FIG. 3. Therefore, it is possible to suppress oscillation.

However, in the case where the regulator circuit is disposed in the region surrounded by the solid line of FIG. 4, that is, a region away from the pad electrode Pd1, even if phase compensation is performed by the phase compensation circuit, the regulator circuit may oscillate.

This is because the wiring resistance Ri1 increases as the wiring length of the intra-chip wiring L1 connecting the regulator circuit and the pad electrode Pd1 increases, and, due to a CR oscillation circuit formed by the wiring resistance Ri1 and the load CL connected in series, a so-called “zero” in which the transfer function becomes zero occurs.

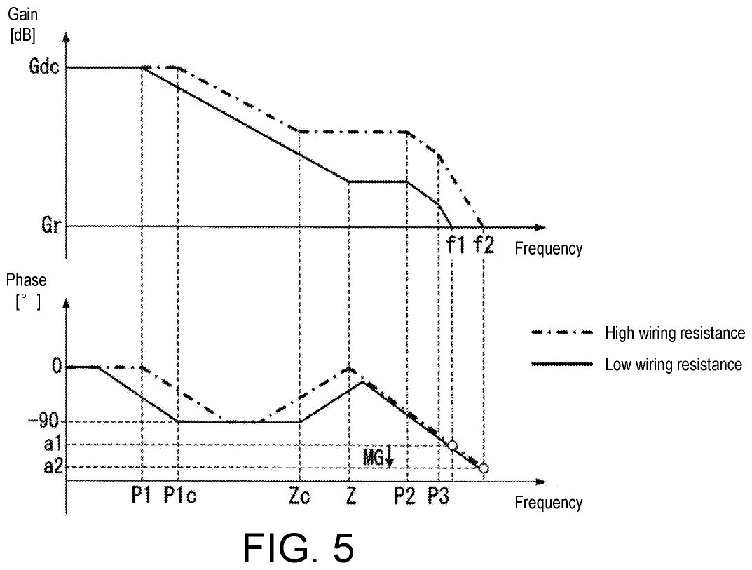

FIG. 5 is a Bode diagram illustrating an example of the frequency properties of the regulator circuit in the case where “zero” appears. In FIG. 5, the solid line illustrates the frequency properties of the conventional regulator circuit in the case where the wiring resistance Ri1 is low, and the dot broken line illustrates the frequency properties of the conventional regulator circuit in the case where the wiring resistance Ri1 is high.

With the appearance of “zero”, as shown in FIG. 5, the decrease in gain at zero frequency (Z: the case where the wiring resistance Ri1 is low, Zc: the case where the wiring resistance Ri1 is high) stops, and the gain is constant from the zero frequency to the second pole frequency P2. Accordingly, as shown in FIG. 5, the constant phase shifts to a phase advance state in which the phase advances as the frequency increases in a frequency band before and after the zero frequency (Z or Zc) including the zero frequency, and shifts to a phase delay state in which the phase is delayed as the frequency increases when the frequency approaches the next pole frequency.

At this time, as shown in FIG. 5, regarding the frequency at which the desired gain Gr is obtained, a frequency f2 in the case where the wiring resistance is large becomes higher than the frequency f1 in the case where the wiring resistance is small, and a phase a1 at the frequency f1 has a greater phase delay than a phase a2 at the frequency f2.

That is, compared with the case where the wiring resistance of the intra-chip wiring connecting the regulator circuit and the pad electrode is small, in the case where the wiring resistance of the intra-chip wiring connecting the regulator circuit and the pad electrode is large, the margin with respect to oscillation is reduced by the phase difference MG as shown in FIG. 5.

In view of the above, the inventors found that, when the wiring length of the wiring in the semiconductor IC chip connecting the pad electrode connected with the capacitive load and the regulator circuit increases, the wiring resistance of the wiring increases, and, equivalently, an RC oscillation circuit in which the wiring resistance is connected in series with the load is formed, and through the RC oscillation circuit, the regulator circuit enters the zero state as shown in FIG. 5. In addition, the inventors found that, in the zero state as shown in FIG. 5, the longer the intra-chip wiring connecting the pad electrode and the regulator circuit, the greater the phase delay of the feedback voltage in the regulator circuit, and the more easily oscillation occurs.

Therefore, in the embodiment shown in FIG. 1, the drain of the output transistor Q1 of the regulator circuit 10 and an end of the feedback resistor R1 are not connected by an intra-chip wiring in the semiconductor IC chip 20. Instead, the drain of the output transistor Q1 of the regulator circuit 10 and an end of the feedback resistor R1 are connected with wirings (W1, W2, JP) external to the semiconductor IC chip 20 via the chip intra-wirings (L1, L2) and the pad electrodes (Pd1, Pd2).

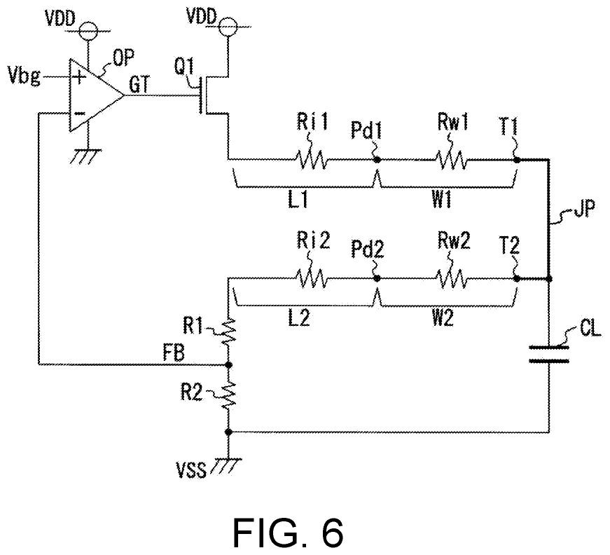

FIG. 6 is an equivalent circuit diagram representing the wiring resistances of the respective wirings connecting the regulator circuit 10, the pad electrodes Pd1 and Pd2 of the semiconductor IC chip 20, the external terminals T1, Tg of the package 30, and the load CL shown in FIG. 1 by using symbols of resistors.

As shown in FIG. 6, in the semiconductor device 100 shown in FIG. 1, resistances Ri1, Ri2 that are the wiring resistances of the intra-chip wirings L1 and L2, respectively, and resistances Rw1 and Rw2 that are the wiring resistances of the bonding wires W1 and W2, respectively, are interposed in the wirings connecting the load CL and the regulator circuit 10.

However, in the semiconductor device 100 shown in FIG. 1, the respective ends of the bonding wires W1 and W2 are connected (short-circuited) by the metal wiring JP, and by connecting the connection point of the metal wiring JP and the bonding wires W1 and W2 to an end of the load CL, the resistance component connected in series with the load CL is eliminated.

Accordingly, regardless of the magnitudes of the wiring resistances Ri1 and RI2 due to the intra-chip wirings L1 and L2, an RC oscillation circuit is not formed in a negative feedback path of the regulator circuit 10. Accordingly, in the regulator circuit 10, the zero state as shown in FIG. 5 does not occur, and it is possible to suppress the oscillation of the regulator circuit 10 that comes together with the zero.

Therefore, according to the disclosure, since the oscillation of the regulator circuit 10 can be suppressed regardless of the position the regulator circuit 10 in the semiconductor IC chip 20, the degree of freedom of the position for disposing another circuit group in the semiconductor IC chip 20 is increased. Accordingly, the chance of having a dead space in the semiconductor IC chip 20 decreases, and it is possible to reduce the chip size and lower the cost.

Although FIG. 1 illustrates the configuration of the semiconductor device 100 at the when the product is shipped, in a test on the semiconductor IC chip 20 alone before the product is shipped, according to the configuration of the semiconductor IC chip 20 as shown in FIG. 1, it is possible to perform a test in a state in which the oscillation of the regulator circuit 10 is suppressed.

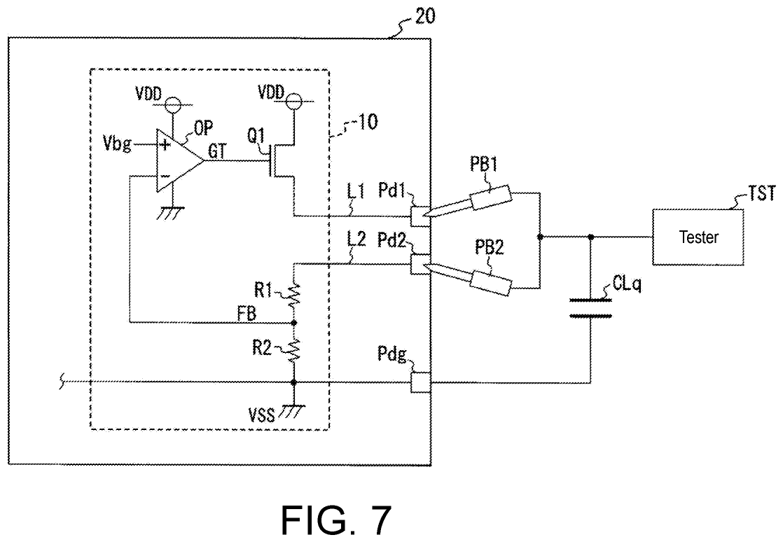

FIG. 7 is a diagram illustrating a configuration of a test system at the time of testing the semiconductor IC chip 20 alone.

As shown in FIG. 7, in the case where a test is performed on the regulator circuit 10 formed in the semiconductor IC chip 20, a capacitive load CLq having the same properties as the load CL is prepared.

Then, the electrodes of two probe needles PB1 and PB2 of a tester TST testing the semiconductor IC chip 20 are connected with each other, and the connection point of the probe needles PB1 and PB2 is connected with an end of the load CLq for testing. Then, the needle tip of the probe needle PB1 is brought into contact with the pad electrode Pd1 of the semiconductor IC chip 20, and the needle tip of the probe needle PB2 is brought into contact with the pad electrode Pd2, thereby starting the test.

Here, the resistance components (parasitic resistances) in the probe needles PB1, PB2 are higher than the resistances of the intra-chip wirings. However, as shown in FIG. 7, since there is no resistance component connected in series with the load CLq for testing, an RC oscillation circuit is not interposed in the negative feedback path of the regulator circuit 10, and the regulator circuit 10 does not enter the zero state as described above.

Thus, according to the semiconductor IC chip 20 shown in FIG. 1, it is possible to perform a test on the regulator circuit in a state in which the oscillation is suppressed.

### Embodiment 2

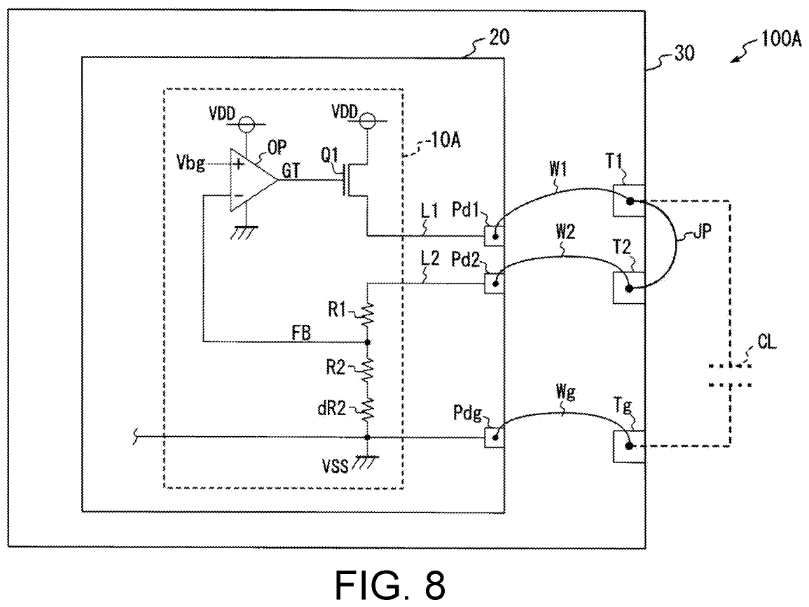

FIG. 8 is a diagram illustrating a configuration of a semiconductor device 100A as a second embodiment according to the disclosure.

The configuration shown in FIG. 8 is the same as the configuration shown in FIG. 1, except for the point that a regulator circuit 10A is adopted in place of the regulator circuit 10.

In the regulator circuit 10A shown in FIG. 8, the configuration is the same as the configuration of the regulator circuit 10 shown in FIG. 1, except for the point that a resistor dR2 for voltage compensation is provided serially between the feedback resistor R1 and the ground voltage VSS.

The resistor dR2 is a resistor responsible for eliminating the error component of the output voltage generated in accordance with the position where the regulator circuit 10A is disposed.

That is, the wiring lengths of the intra-chip wirings L1 and L2 connecting the regulator circuit 10A and the pad electrodes Pd1 and Pd2, respectively, differ in accordance with the position where the regulator circuit 10A is disposed in the semiconductor IC chip 20. That is, the wiring lengths of the intra-chip wirings L1 and L2 differ in accordance with the position where the regulator circuit 10A is disposed in the semiconductor IC chip 20, and the resistances values of the wiring resistances (Ri1, Ri2) coming with the wiring lengths of the intra-chip wirings L1 and L2 also differ in accordance with the position where the regulator circuit 10A is disposed. For such reason, an error may occur in the output voltage output from the regulator circuit 10A.

Therefore, in the regulator circuit 10A, the error component is eliminated by the resistor dR2 connected in series with the feedback resistors R1 and R2.

The resistance value of the resistor dR2 is determined according to the following.

Firstly, an ideal output voltage Vo of the regulator circuit 10A in which the resistance value of each of the wiring resistances Ri1 and Ri2 is set as zero is represented as follows:

Vo=I·(R1+R2)/R2
I: output current

Meanwhile, an actual output voltage VoA of the regulator circuit 10A taking into consideration the wiring resistances Ri1 and Ri2 is represented as follows:

VoA=I·(R1+R2+dR2+Ri2)/(R2+dR2)

Here, in order to eliminate the error between the ideal output voltage Vo and the actual output voltage VoA, it is set that:

when Vo=VoA,

then dR2=R2·Ri2/R1

Accordingly, by providing the resistor dR2 having the resistance value as represented above, the error of the output voltage of the regulator circuit 10A due to the wiring resistances Ri1 and Ri2 is reduced.

### Embodiment 3

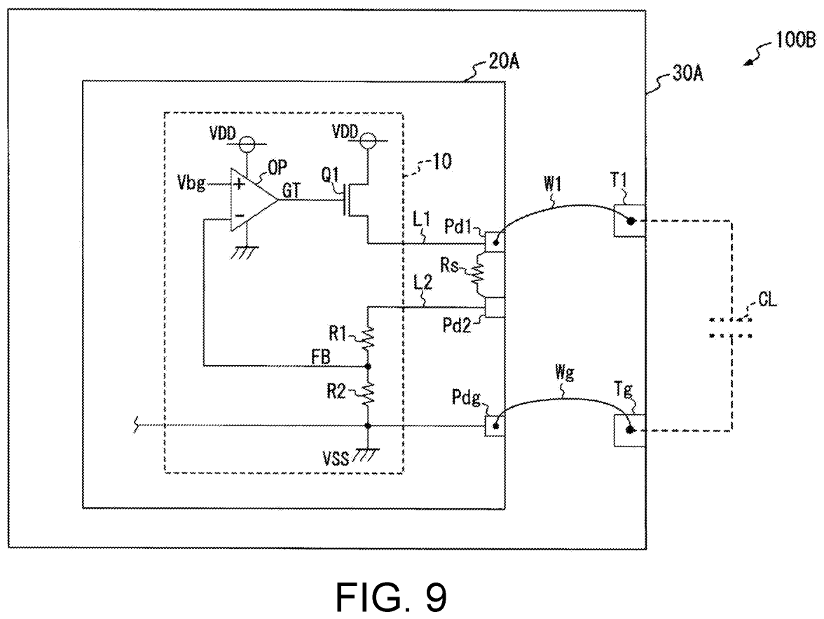

FIG. 9 is a diagram illustrating a configuration of a semiconductor device 100B as a third embodiment according to the disclosure.

In the configuration shown in FIG. 9, the configuration except for the point that a semiconductor IC chip 20A and a package 30A are adopted in place of the semiconductor IC chip 20 and the package 30, that is, the configuration about the regulator circuit 10, is the same as the configuration shown in FIG. 1.

The package 30A is a package in which the bonding wire W2, the metal wiring JP, and the external terminal T2 are omitted from the package 30 shown in FIG. 1. In the semiconductor IC chip 20A, the configuration except for the point that an inter-pad resistor Rs for stability compensation is provided between the pad electrodes Pd1 and Pd2 is the same as the semiconductor IC chip 20 shown in FIG. 1.

That is, in the semiconductor device 100B, by providing the inter-pad resistor Rs connecting the pad electrodes Pd1 and Pd2, the single bonding wire W1 is provided for the two bonding wires (W1, W2) required in the configuration shown in FIG. 1.

Meanwhile, the number of the bonding wire can be one by short-circuiting the pad electrodes Pd1 and Pd2 by using a metal wiring as well.

However, when the semiconductor IC chip 20A is tested alone, a probe needle having a higher parasitic resistance (tens of ohm) is brought into contact with the pad electrode Pd1 or Pd2, so the parasitic resistance of the probe needle is connected in series with the capacitive load. Accordingly, an RC oscillation circuit is formed by the parasitic resistance of the probe needle and the capacitive load, and, accordingly, the regulator circuit enters the zero state as described above. Therefore, during the test, there is a concern that the regulator circuit may oscillate.

Thus, in the semiconductor IC chip 20A shown in FIG. 9, the inter-pad resistor Rs having a higher resistance value connects the pad electrodes Pd1 and Pd2.

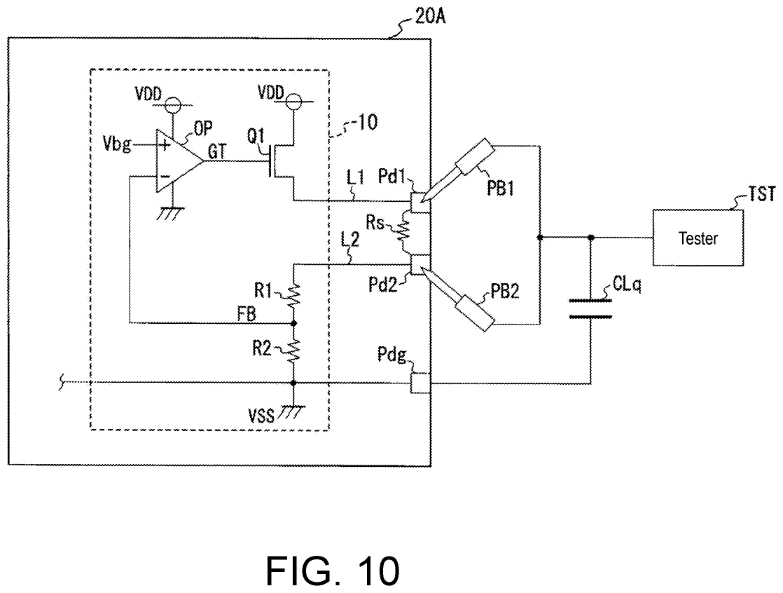

When the semiconductor IC chip 20A is tested, as shown in FIG. 10, the test starts by bringing the needle tips of the two probe needles PB1 and PB2 of the tester TST into contact with the pad electrodes Pd1 and Pd2. It is noted that the electrodes of the probe needles PB1 and PB2 are connected with each other as shown in FIG. 10, and the connection point of the electrodes is connected with an end of the load CLq for testing.

Accordingly, even if the probe needles PB1 and PB2 having parasitic resistances are interposed, there is no resistance component connected in series with the load CL1 for testing. Therefore, it is possible to avoid the zero state and perform the test without oscillating the regulator circuit 10.

As shown in FIG. 6, although the parasitic resistances of the bonding wires (W1, W2) are also connected in series with the load (CL, CLq) together with the wiring resistances (Wi1, Wi2) of the intra-chip wirings (L1, L2), such parasitic resistances are too low to substantially form an RC oscillation circuit.

However, when the resistance value of the inter-pad resistor Rs connected between the pad electrodes Pd1 and Pd2 is too high, the maximum operation range of the differential amplifier Op and the output transistor Q1 may be exceeded, and the gain of the negative feedback may decrease. Thus, the feedback voltage FB may not entirely follow the reference voltage Vbg, and the output voltage becomes unstable.

Therefore, the resistance value of the inter-pad resistor Rs is set as follows:

10·RP<Rs<R1+R2,
Rp: the parasitic resistance of the probe needle Pb1, Pb2

Meanwhile, in the case where the configuration shown in FIG. 9 is adopted, at the time of testing, the wiring resistance Ri1 of the intra-chip wiring L1, the wiring resistance Ri2 of the intra-chip wiring L2, the parasitic resistance Rp of each of the probe needles PB1 and PB2, and the inter-pad resistor Rs for stability compensation are interposed.

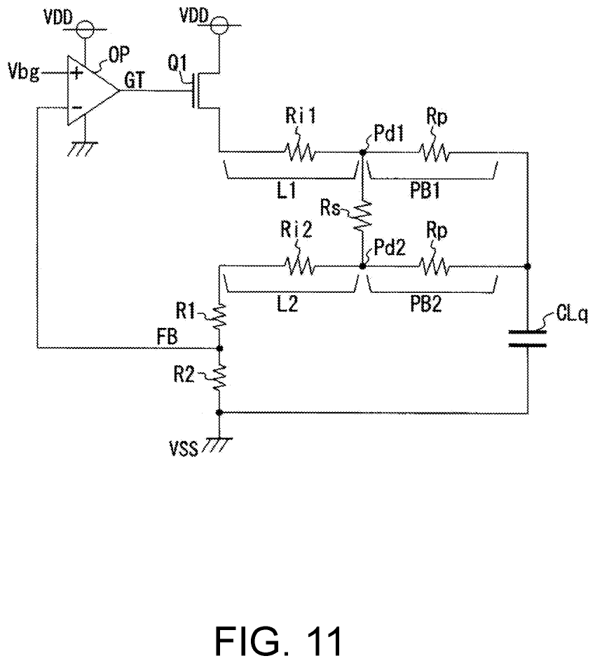

FIG. 11 is an equivalent circuit diagram representing the parasitic resistance Rp and the wiring resistances Ri1, Ri2 of respective wirings connecting the regulator circuit 10, the pad electrodes Pd1 and Pd2 of the semiconductor IC chip 20A, the external terminals T1, Tg of the package 30, and the load CLq by using symbols of resistors in the test system shown in FIG. 10.

Through the inter-pad resistor Rs, the wiring resistances Ri1 and Ri2, and the parasitic resistance Rp of each of the probe needles PB1 and PB2, an error occurs in the output voltage of the regulator circuit 10.

Therefore, the resistance values of the feedback resistors R1 and R2 are trimmed and determined as follows to remove such error component.

Firstly, the ideal output voltage Vo of the regulator circuit 10 in the case where the respective resistance values of the wiring resistances Ri1, Ri2 and the respective parasitic resistances of the probe needles PB1 and PB2 are set as zero is represented as follows:

Vo=I·(R1+R2)/R2
I: output current

With the inter-pad resistor Rs, the parasitic resistance Rp of the probe needle PB1, and the parasitic resistance Rp of the probe needle PB2, the resistance interposed in the feedback path shown in FIG. 11 is considered as 2·Rp.

Then, the actual output voltage VoA of the regulator circuit 10 obtained by trimming the feedback resistors R1 and R2 is represented as follows:

VoA=(R1t+R2t+Ri2+2·Rp)·I/R2t,

R1b+R2b=R1t+R2t=Ra,
R1b: the resistance value of the feedback resistor R1 before trimming
R1t: the resistance value of the feedback resistor R1 after trimming
R2b: the resistance value of the feedback resistor R2 before trimming
R2t: the resistance value of the feedback resistor R2 after trimming

Here, in order to eliminate the error between the ideal output voltage Vo and the actual output voltage VoA, it is set that:

$$when Vo = VoA , \\ \begin{matrix}then R 2 t = ( Ra + Ri 2 + 2 \cdot Rp ) \cdot R 2 b / Ra \\ = [ 1 + ( Ri 2 + 2 \cdot Rp ) / Ra ] \cdot R 2 b\end{matrix} \\ R 1 t = Ra - R 2 t$$

Accordingly, by setting the resistance value of the feedback resistor R1 shown in FIG. 9 as R1t and the resistance value of the feedback resistor R2 as shown in FIG. 9 as R2t, adjustments are made to eliminate the error component that occurs in the output voltage of the regulator circuit 10.

As described above, according to the semiconductor device 100B shown in FIG. 9, like the semiconductor device 100 shown in FIG. 1, it is possible to suppress the oscillation of the regulator circuit 10 not only after the product is shipped but also at the time when the semiconductor IC chip 20A is tested alone, regardless of the position where the regulator circuit is disposed in the semiconductor IC chip 20A.

In addition, by adopting the configuration shown in FIG. 9, the number of bonding wires can be cut by one, so it is possible to further reduce the product cost.

### Embodiment 4

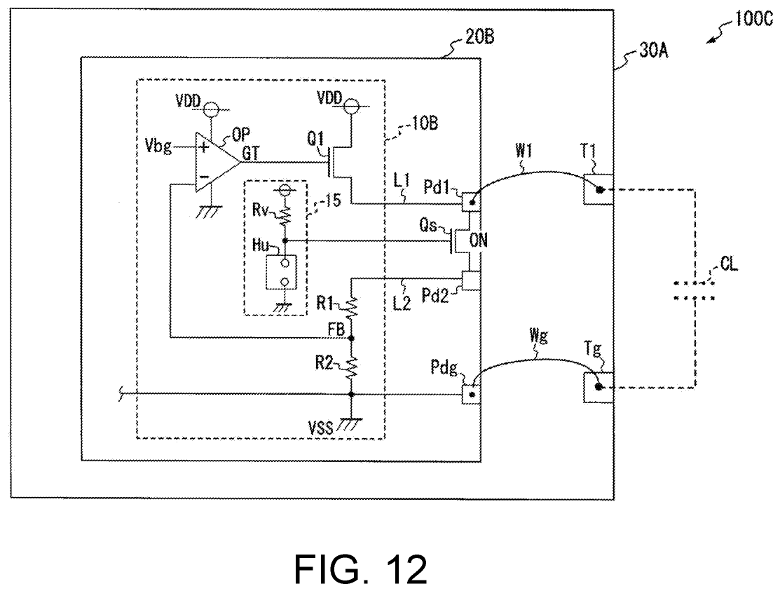

FIG. 12 is a diagram illustrating a configuration of a semiconductor device 100C as a fourth embodiment according to the disclosure.

In the configuration shown in FIG. 12, the configuration except for the point that a regulator circuit 10B and a semiconductor IC chip 20B are adopted in place of the regulator circuit and the semiconductor IC chip 20A, that is, the configuration about the package 30A, is the same as the configuration shown in FIG. 9.

In addition, in the semiconductor IC chip 20B shown in FIG. 12, the configuration is the same as the configuration of the semiconductor IC chip 20A shown in FIG. 9, except for the point that an N-channel MOS transistor Qs is adopted in place of the inter-pad resistor Rs connecting the pad electrodes Pd1 and Pd2. In addition, in the regulator circuit 10B shown in FIG. 12, the configuration (OP, Q1, R1, R2) is the same as the regulator circuit 10 shown in FIG. 9, except for the point that a control circuit 15 controlling ON/OFF of the transistor Qs is newly provided.

In FIG. 12, the drain of the transistor Qs is connected with the pad electrode Pd1, and the source of the transistor Qs is connected with the pad electrode Pd2.

The control circuit 15 includes a pull-up resistor Rv and a fuse element Hu. An end of the pull-up resistor Rv receives the power voltage VDD, and the other end of the pull-up resistor Rv is connected with an end of the fuse and the gate of the transistor Qs. The ground voltage VSS is applied to the other end of the fuse element Hu.

In the case where the fuse element Hu is not cut off, the control circuit 15 supplies an ON/OFF control signal having the ground voltage VSS to the gate of the transistor Qs. Meanwhile, in the case where the fuse element Hu is cut off, the control circuit 15 supplies an ON/OFF control signal having the power voltage VDD to the gate of the transistor Qs.

In the case of receiving the ON/OFF control signal having the power voltage VDD from the control circuit 15, the transistor Qs becomes ON, and connects the pad electrodes Pd1 and Pd2 via the ON resistance of the transistor Qs itself. In the case where the transistor Qs receives the ON/OFF control signal having the ground voltage VSS from the control circuit 15, the transistor Qs becomes OFF and cuts off the electrical connection between the pad electrodes Pd1 and Pd2. Compared with the case of generating the ON/OFF signal by using a transistor, with the control circuit 15 using the fuse element Hu, the cost can be suppressed.

Here, immediately after the manufacture of the semiconductor IC chip 20B, the fuse element Hu of the control circuit 15 is not cut off, and the transistor Qs is in the OFF state. In the case where the fuse element Hu is not cut off, although a current flows to the pull-up resistor Rv via the fuse element Hu, the current value of the current can be suppressed by using the resistance value of the pull-up resistor Rv. Therefore, it is possible to suppress the increase in power consumption.

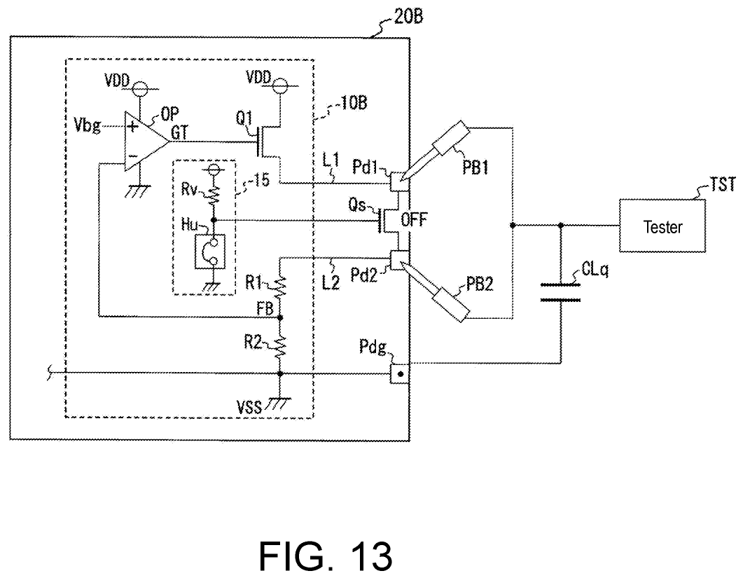

FIG. 13 is a diagram illustrating a configuration of a test system at the time of testing the semiconductor IC chip 20B.

In the test system shown in FIG. 13, the configuration is the same as the configuration shown in FIG. 7, except that the semiconductor IC chip 20B serves as a test target in place of the semiconductor IC chip 20.

As shown in FIG. 13, when the semiconductor IC chip 20B is tested alone, the fuse element Hu of the control circuit 15 is not cut off, so the transistor Qs is in the OFF state. Accordingly, the test is performed in a state in which the needle tips of the probe needles PB1 and PB2 are brought into contact with the pad electrodes Pd1 and Pd2, respectively, that are in a state in which the mutual electrical connection is cut off, as shown in FIG. 13. At this time, the equivalent resistance of the transistor Qs in the OFF state is higher than the resistance components (parasitic resistances) in the probe needles PB1 and PB2. Nevertheless, as shown in FIG. 13, no resistance component is connected in series with the load CLq. Accordingly, an RC oscillation circuit is not included in the negative feedback path of the regulator circuit 10B, and the regulator circuit 10B does not enter the zero state. Therefore, it is possible to perform the test without generating oscillation in the regulator circuit 10B.

Then, after the test on the semiconductor IC chip 20B alone is completed, the fuse element Hu of the control circuit 15 is cut off, and a packaging process as follows is performed. That is, as shown in FIG. 12, the semiconductor IC chip 20B is fixedly disposed in the package 30A, and the pad electrodes Pd1 and Pd2 of the semiconductor IC chip 20B and the external terminals T1 and Tg of the package 30 are connected by the bonding wires W1 and Wg.

Accordingly, since the fuse element Hu of the control circuit 15 is cut off after the packaging process, the transistor Qs is maintained to be ON, and the pad electrodes Pd1 and Pd2 of the semiconductor IC chip 20B are connected via the ON resistance of the transistor Qs. Accordingly, the resistance component connected in series with respect to the load CL connected between the external terminals T1 and Tg of the package 30 is eliminated, and an RC oscillation circuit is not interposed in the negative feedback path of the regulator circuit 10B. Accordingly, since the regulator circuit 10B is not in the zero state, the oscillation of the regulator circuit 10B is suppressed.

In this way, according to the semiconductor device 100C shown in FIG. 12, like the semiconductor device 100B shown in FIG. 9, it is possible to suppress the oscillation of the regulator circuit 10B not only after the product is shipped but also at the time when the semiconductor IC chip 20B is tested alone, regardless of the position where the regulator circuit 10B is disposed in the semiconductor IC chip 20B.

In addition, by adopting the configuration shown in FIG. 12, the number of bonding wires can be cut by one from the configuration shown in FIG. 1, so it is possible to further reduce the product cost.

### Embodiment 5

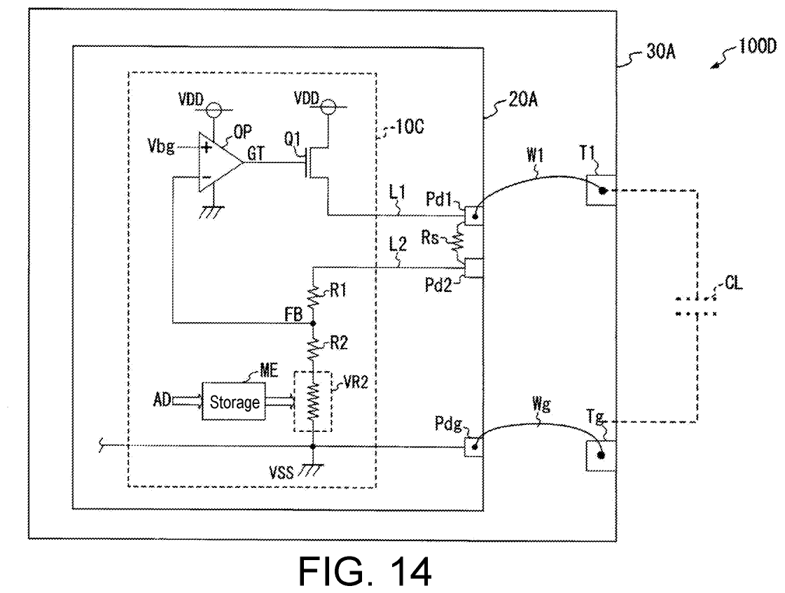

FIG. 14 is a diagram illustrating a configuration of a semiconductor device 100D as a fifth embodiment according to the disclosure.

In the configuration shown in FIG. 14, the configuration except for the point that a regulator circuit 10C is adopted in place of the regulator circuit 10, that is, the configuration about the semiconductor IC chip 20A and the package 30A, is the same as the configuration shown in FIG. 9.

In addition, in the regulator circuit 10C, the configuration is the same as the regular circuit 10 shown in FIG. 9, except for the point that a variable resistor circuit VR2 for voltage compensation is provided serially between the feedback resistor R2 and the ground voltage VSS, and a memory ME controlling the resistance value of the variable resistor circuit VR2 is provided.

The variable resistor circuit VR2 is a variable resistor able to set the resistance value of the variable resistor circuit VR2 itself to one of first to N^{th} resistance values in N (N being an integer of 2 or more) stages. The resistance value is set to a resistance value specified in resistance specification data read from the memory ME.

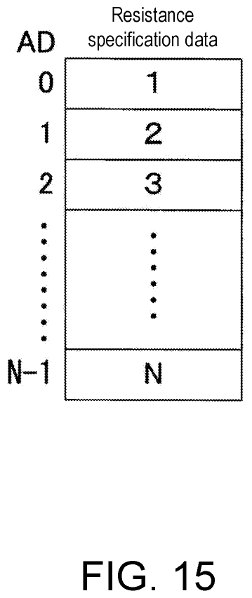

The memory ME stores in advance the resistance specification data by associating with an address AD as shown in FIG. 15, for example, and individually specifying the first to N^{th} resistance values in the variable resistor circuit VR2.

That is, the memory ME and the variable resistor circuit VR2 is a variable resistor in which the resistance value of the variable resistor itself is set to an arbitrary resistance value in the first to N^{th} resistance values according to the address AD, and is provided in place of the resistor dR2 with a fixed resistance value as shown in FIG. 8.

That is, since the resistance value of the resistor dR2 shown in FIG. 8 is fixed, when the wiring resistance (Wi1, Wi2) of the intra-chip wiring (L1, L2) or the parasitic resistance (Rp) of the probe needle (PB1, PB2) varies due to manufacture variations, the output voltage of the regulator circuit also varies.

Therefore, in the regulator circuit 10C, after the packaging process or when the semiconductor IC chip 20A is tested alone, by varying the resistance value of the variable resistor circuit VR2 in accordance with the address AD, the output voltage of the regulator circuit 10C can be adjusted to the ideal value. Regarding the memory ME and the variable resistor circuit VR2, a configuration same as the configuration shown in FIG. 14 may also be provided in the semiconductor IC chip 20 shown in FIG. 1 or the semiconductor IC chip 20B shown in FIG. 12, in addition to the semiconductor IC chip 20A shown in FIG. 14.

As described above, in the semiconductor IC chip (20, 20A, 20B) shown in Embodiments 1 to 5, the output transistor Q1 included in the regulator circuit (10, 10A to 10C) is not connected with the feedback resistor R1 directly. That is, the configuration in which the output transistor Q1 is connected with the pad electrode Pd1 via the intra-chip wiring L1 and the feedback resistor R1 is connected with the pad electrode Pd2 via the intra-chip wiring L2 is adopted, and the output transistor Q1 and the feedback resistor R1 are electrically connected between the pad electrodes Pd1 and Pd2, or electrically connected at the outside of the semiconductor IC chip via the pad electrodes Pd1 and Pd2.

That is, the pad electrodes Pd1 and Pd2 are connected by the metal wiring JP via the bonding wires W1, W2 and the external terminals T1 and T2 of the package 30, as shown in FIG. 1. Alternatively, the pad electrodes Pd1 and Pd2 are connected by the resistor Rs as shown in FIG. 9 or by the transistor Qs as shown in FIG. 12. In addition, the connection point of the pad electrodes Pd1 and Pd2 with the resistor Rs or the transistor Qs is connected with the load CL. Accordingly, in the negative feedback path of the regulator circuit, there is no resistance component connected in series with the load CL. Accordingly, regardless of the position where the regulator circuit is disposed in the semiconductor IC chip, it is possible to prevent the regulator circuit from entering the zero state, thereby suppressing the oscillation of the regulator circuit.

Although the configuration for preventing oscillation is described by adopting the regulator circuit (10, 10A, 10C) generating a constant voltage as an example, the circuit as the target of oscillation prevention is not limited to a regulator circuit. That is, in the disclosure, it suffices as long as a circuit that generates an output voltage by transmitting a current corresponding to the difference between the input voltage (Vbg) and the feedback voltage (FB), namely a negative feedback amplification circuit, serves as the target of oscillation prevention.

In brief, as the semiconductor device (100, 100A to 100D) according to the disclosure, it suffices as long as a semiconductor device has a semiconductor IC chip in which a negative feedback amplification circuit and a feedback resistor as follows are formed.

That is, the negative feedback amplification circuit (e.g., the differential amplifier OP and the output transistor Q1) generates the output voltage supplied to the capacitive load (CL) by transmitting the current corresponding to the difference between the input voltage (Vbg) and the feedback voltage (FB) to the first pad (Pd1) via the first wiring (L1). The feedback resistor (e.g., the feedback resistors R1, R2) receives the voltage received by the second pad (Pd2) via the second wiring (L2) not connected with the first wiring, and generates, as the feedback voltage (FB), a voltage obtained by dividing the voltage received via the second wiring.

What is claimed is:

1. A semiconductor device, having a semiconductor IC chip, the semiconductor IC chip being formed with:
a first pad and a second pad;
a feedback amplification circuit, generating an output voltage supplied to a capacitive load by transmitting a current corresponding to a difference between an input voltage and a feedback voltage to the first pad via a first wiring; and
a feedback resistor, receiving a voltage received by the second pad via a second wiring not connected with the first wiring, and generating, as the feedback voltage, a voltage obtained by dividing the voltage received via the second wiring.

2. The semiconductor device as claimed in claim 1, comprising:
a package, accommodating the semiconductor IC chip,
wherein the package comprises:
a first external terminal for externally connecting an end of the capacitive load;
a second external terminal;
a first bonding wire, connecting the first pad and the first external terminal;
a second bonding wire, connecting the second pad and the second external terminal; and
a metal wiring, short-circuiting the first external terminal and the second external terminal.

3. The semiconductor device as claimed in claim 1, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
the semiconductor IC chip comprises a voltage compensation resistor connected in series with the first resistor and the second resistor.

4. The semiconductor device as claimed in claim 3, wherein the voltage compensation resistor is a resistor having a resistance value represented as follows:
dR2=R2·Ri2/R1,
wherein dR2 represents the resistance value of the voltage compensation resistor,
R1 represents a resistance value of the first resistor,
R2 represents a resistance value of the second resistor, and
Ri2 represents a wiring resistance of the second wiring.

5. The semiconductor device as claimed in claim 1, wherein the semiconductor IC chip comprises an inter-pad resistor, an end of the inter-pad resistor is connected with the first pad, and an other end of the inter-pad resistor is connected with the second pad.

6. The semiconductor device as claimed in claim 5, comprising:
a package, accommodating the semiconductor IC chip,
wherein the package comprises:
a first external terminal for externally connecting an end of the capacitive load; and
a first bonding wire, connecting the first pad and the first external terminal.

7. The semiconductor device as claimed in claim 1, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
wherein the output voltage is adjusted by trimming each of the first resistor and the second resistor to exhibit a resistance value represented as follows:
R2t=[1+(Ri2+2·Rp)/Ra]·R2b,
R1t=Ra−R2t,
Ra=R1b+R2b=R1t+R2t,
wherein R1b represents a resistance value of the first resistor before trimming,
R1t represents a resistance value of the first resistor after trimming,
R2b represents a resistance value of the second resistor before trimming,
R2t represents a resistance value of the second resistor after trimming,
Ri2 represents a wiring resistance of the second wiring, and
Rp represents a parasitic resistance of a probe needle brought into contact with the first pad at a time of testing the semiconductor IC chip.

8. The semiconductor device as claimed in claim 1, wherein the semiconductor IC chip comprises a transistor, and the transistor receives an ON/OFF control signal by using a gate of the transistor itself, connects the first pad and the second pad via an ON resistance of the transistor itself in a case where an ON state is set in accordance with the ON/OFF control signal, and cuts off electrical connection between the first pad and the second pad in a case where an OFF state is set in accordance with the ON/OFF control signal.

9. The semiconductor device as claimed in claim 8, wherein the semiconductor IC chip comprises a control circuit,
the control circuit comprises: a pull-up resistor, receiving a power voltage by using an end; and a fuse element, wherein an other end of the pull-up resistor is connected with an end of the fuse element itself, and a ground voltage is applied to an other end of the fuse element itself, and the control circuit supplies, as the ON/OFF control signal, a signal having a voltage generated at the end of the pull-up resistor to a gate of the transistor.

10. The semiconductor device as claimed in claim 1, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
the semiconductor IC chip comprises:
a variable resistor, which is connected in series with the first resistor and the second resistor, and in which a resistance value of the variable resistor itself is set to a resistance value specified by resistance specification data; and
a memory, storing in advance first to N^{th} data pieces specifying respectively different resistance values by associating the first to N^{th} data pieces with respective addresses, N being an integer of 2 or more, wherein, in a case of receiving one of the addresses, the memory reads a data piece corresponding to the address from the first to N^{th} data pieces and supplies the data piece, as the resistance specification data, to the variable resistor.

11. The semiconductor device as claimed in claim 2, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
the semiconductor IC chip comprises a voltage compensation resistor connected in series with the first resistor and the second resistor.

12. The semiconductor device as claimed in claim 11, wherein the voltage compensation resistor is a resistor having a resistance value represented as follows:
dR2=R2·Ri2/R1,
wherein dR2 represents the resistance value of the voltage compensation resistor,
R1 represents a resistance value of the first resistor,
R2 represents a resistance value of the second resistor, and
Ri2 represents a wiring resistance of the second wiring.

13. The semiconductor device as claimed in claim 5, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
wherein the output voltage is adjusted by trimming each of the first resistor and the second resistor to exhibit a resistance value represented as follows:
R2t=[1+(Ri2+2·Rp)/Ra]·R2b,
R1t=Ra−R2t,
Ra=R1b+R2b=R1t+R2t,
wherein R1b represents a resistance value of the first resistor before trimming,
R1t represents a resistance value of the first resistor after trimming,
R2b represents a resistance value of the second resistor before trimming,
R2t represents a resistance value of the second resistor after trimming,
Ri2 represents a wiring resistance of the second wiring, and
Rp represents a parasitic resistance of a probe needle brought into contact with the first pad at a time of testing the semiconductor IC chip.

14. The semiconductor device as claimed in claim 5, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
the semiconductor IC chip comprises:
a variable resistor, which is connected in series with the first resistor and the second resistor, and in which a resistance value of the variable resistor itself is set to a resistance value specified by resistance specification data; and
a memory, storing in advance first to N^{th} data pieces specifying respectively different resistance values by associating the first to N^{th} data pieces with respective addresses, N being an integer of 2 or more, wherein, in a case of receiving one of the addresses, the memory reads a data piece corresponding to the address from the first to N^{th} data pieces and supplies the data piece, as the resistance specification data, to the variable resistor.

15. The semiconductor device as claimed in claim 8, wherein the feedback resistor comprises: a first resistor, wherein an end of the first resistor is connected with the second wiring; and a second resistor, wherein an end of the second resistor is connected with an other end of the first resistor, and the feedback resistor generates, as the feedback voltage, a voltage generated at a connection point of the first resistor and the second resistor, and
the semiconductor IC chip comprises:
a variable resistor, which is connected in series with the first resistor and the second resistor, and in which a resistance value of the variable resistor itself is set to a resistance value specified by resistance specification data; and
a memory, storing in advance first to N^{th} data pieces specifying respectively different resistance values by associating the first to N^{th} data pieces with respective addresses, N being an integer of 2 or more, wherein, in a case of receiving one of the addresses, the memory reads a data piece corresponding to the address from the first to N^{th} data pieces and supplies the data piece, as the resistance specification data, to the variable resistor.

16. A test method for performing a test on the semiconductor IC chip as claimed in claim 1 by using a tester having a first probe needle and a second probe needle,
wherein the first probe needle and the second probe needle are commonly connected to an end of a capacitive load for testing, and
the test is performed in a state in which a needle tip of the first probe needle is brought into contact with the first pad of the semiconductor IC chip as claimed in claim 1 and a needle tip of the second probe needle is brought into contact with the second pad of the semiconductor IC chip as claimed in claim 1.
